(19) United States
(12) Patent Application Publication
(10) Pub. No.: US 2022/0341973 A1
(43) Pub. Date: Oct. 27, 2022

(54) TEMPERATURE-INSENSITIVE CURRENT SENSING FOR POWER STAGE

(71) Applicant: Cirrus Logic International Semiconductor Ltd., Edinburgh (GB)

(72) Inventors: Yongjie CHENG, Austin, TX (US); Ruoxin JIANG, Austin, TX (US); Lingli ZHANG, Austin, TX (US); John L. MELANSON, Austin, TX (US)

(73) Assignee: Cirrus Logic International Semiconductor Ltd., Edinburgh (GB)

(21) Appl. No.: 17/236,680

(22) Filed: Apr. 21, 2021

(51) Int. Cl. G01R 19/10; H03K 17/687

(52) U.S. Cl. CPC G01R 19/10; H03K 17/6871

(57) ABSTRACT

A system may include an output power stage driver comprising a plurality of parallel-coupled field-effect transistors and a current sensor comprising a sense field-effect transistor matched to a matched field-effect transistor of the plurality of parallel-coupled field-effect transistors and gate-coupled and source-coupled to the matched field-effect transistor. The current sensor may be configured to measure a reference voltage across the sense field-effect transistor, measure a sense voltage across the matched field-effect transistor, and determine a current through the output power stage driver based on a comparison of the reference voltage to the sense voltage.

### FIELD OF DISCLOSURE

The present disclosure generally relates to an integrated circuit, and, more particularly, to systems and methods for temperature-insensitive current sensing in a power stage, for example a switched output stage of a power converter.

### BACKGROUND

Many electronic devices on the market today often use power converters to convert electric energy from one form to another (e.g., converting between alternating current and direct current), amplifying a voltage or current of an electrical signal, modifying a frequency of an electrical signal, or some combination of the above. Examples of power converters may include boost converters, buck converters, and audio amplifiers (including, but not limited to, Class D and Class H amplifiers). Such power converters often employ a switched output stage, an example of which is shown in FIG. 1. In FIG. 1, switched output stage 100 comprises a pull-up device 102 (e.g., a switch, a p-type metal-oxide-semiconductor field effect transistor, etc.) coupled at its non-gate terminals between a supply voltage and an output node and a pull-down device 104 (e.g., a switch, an n-type metal-oxide-semiconductor field effect transistor, etc.) coupled at its non-gate terminals between a ground voltage and the output node. Predriver circuitry 106 may receive an input voltage v_{IN} (typically a pulse-width-modulated input voltage signal) and apply control logic and/or buffering to such input voltage to drive a pull-up device driving signal voltage v_{P} to the gate terminal of pull-up device 102 and to drive a pull-down device driving signal voltage v_{N} to the gate terminal of pull-down device 104, wherein v_{P} and v_{N} are each a function of v_{IN} Accordingly, switched output stage 100 generates an output voltage v_{OUT} to its output node which is a function of v_{IN}.

For various reasons, it may be desirable to sense an output current i_{OUT} being driven by switched output stage 100. One approach for sensing such output current join i_{OUT} to sense a current flowing through either or both of pull-up device 102 and pull-down device 104. FIG. 2 illustrates an example approach for sensing output current i_{OUT}, as is known in the art. As shown in FIG. 2, a current sensor 200 may include a variable current source 202 (e.g., a current digital-to-analog converter) to generate a variable current i_{SNS}. Variable current i_{SNS} may be driven through a sense pull-down device 204 and a sense resistor 206 in series with sense pull-down device 204. In these existing approaches, pull-down device 104 may be sized to be many orders of magnitude larger than sense pull-down device 204, as large transistor devices may be required to drive signals, but smaller transistor devices may be suitable for sensing applications. A resistance R_{SNS} for sense resistor 206 may be selected such that the combined resistance of sense pull-down device 204 and sense resistor 206 matches the combined resistance of pull-down device 104 and any parasitic resistance R_{PARA} (e.g., resistances of metal traces used to implement switched output stage 100) in series with pull-down device 104. If the impedance of the sense path (e.g., combined impedances of sense pull-down device 204 and sense resistor 206) matches the impedance of the pull-down path of switched output stage 100 (e.g., combined impedances of pull-down device 104 and any series impedance), a fixed current ratio α may exist between the sense path and the pull-down path of switched output stage 100. With such fixed current ratio, a comparator 208 may compare a reference voltage v_{REF} across the sense path to a voltage v_{OUT} across the pull-down path of switched output stage 100, and if v_{REF}=v_{OUT}, then output current i_{OUT} may equal the product of fixed current ratio α and variable current i_{SNS} (e.g., i_{OUT}=αi_{SNS}).

Although the foregoing paragraph contemplates current sensing of the pull-down path of switched output stage 100, an equivalent dual of current sensor 200 may be used for current sensing of the pull-up path of switched output stage 100.

Among the disadvantages of current sensor 200 is that parasitic impedance of the pull-down path of switched output stage 100 may be significant—as high as one-third or more of the total impedance of the pull-down path of switched output stage 100. Because such impedance may vary significantly with changes in temperature, fixed current ratio α may vary with temperature, leading to sensor inaccuracy.

### SUMMARY

In accordance with the teachings of the present disclosure, certain disadvantages and problems associated with existing approaches to current sensing in a power stage may be reduced or eliminated.

In accordance with embodiments of the present disclosure, a system may include an output power stage driver comprising a plurality of parallel-coupled field-effect transistors and a current sensor comprising a sense field-effect transistor matched to a matched field-effect transistor of the plurality of parallel-coupled field-effect transistors and gate-coupled and source-coupled to the matched field-effect transistor. The current sensor may be configured to measure a reference voltage across the sense field-effect transistor, measure a sense voltage across the matched field-effect transistor, and determine a current through the output power stage driver based on a comparison of the reference voltage to the sense voltage.

In accordance with these and other embodiments of the present disclosure, a method may include, in a system including an output power stage driver comprising a plurality of parallel-coupled field-effect transistors: measuring a reference voltage across a sense field-effect transistor matched to a matched field-effect transistor of the plurality of parallel-coupled field-effect transistors and gate-coupled and source-coupled to the matched field-effect transistor, measuring a sense voltage across the matched field-effect transistor, and determining a current through the output power stage driver based on a comparison of the reference voltage to the sense voltage.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a switched output stage for a power converter, as is known in the art;

FIG. 2 illustrates an example approach for sensing an output current in a switched output stage, as is known in the art;

FIG. 3 illustrates selected components of an example switched output stage for a power converter, in accordance with embodiments of the present disclosure; and

FIG. 4 illustrates selected components of another example switched output stage for a power converter, in accordance with embodiments of the present disclosure.

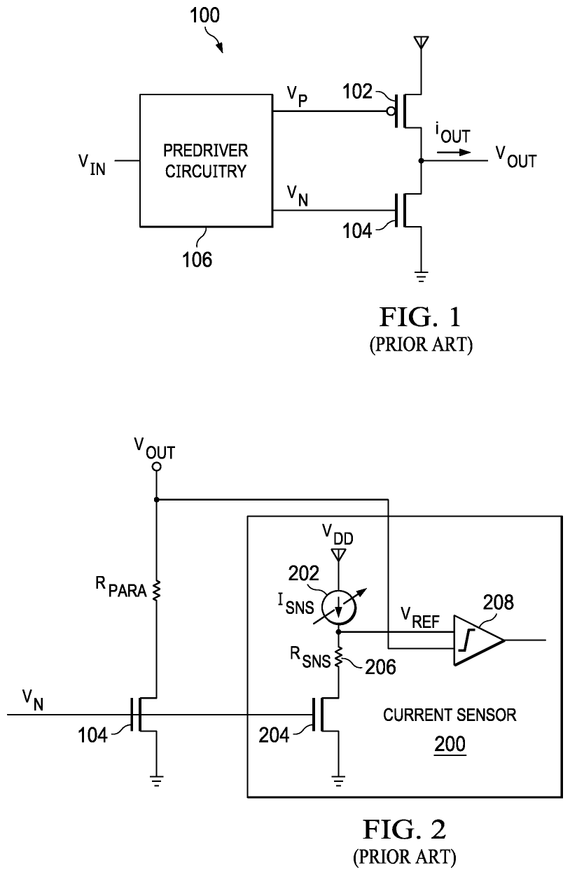

### DETAILED DESCRIPTION

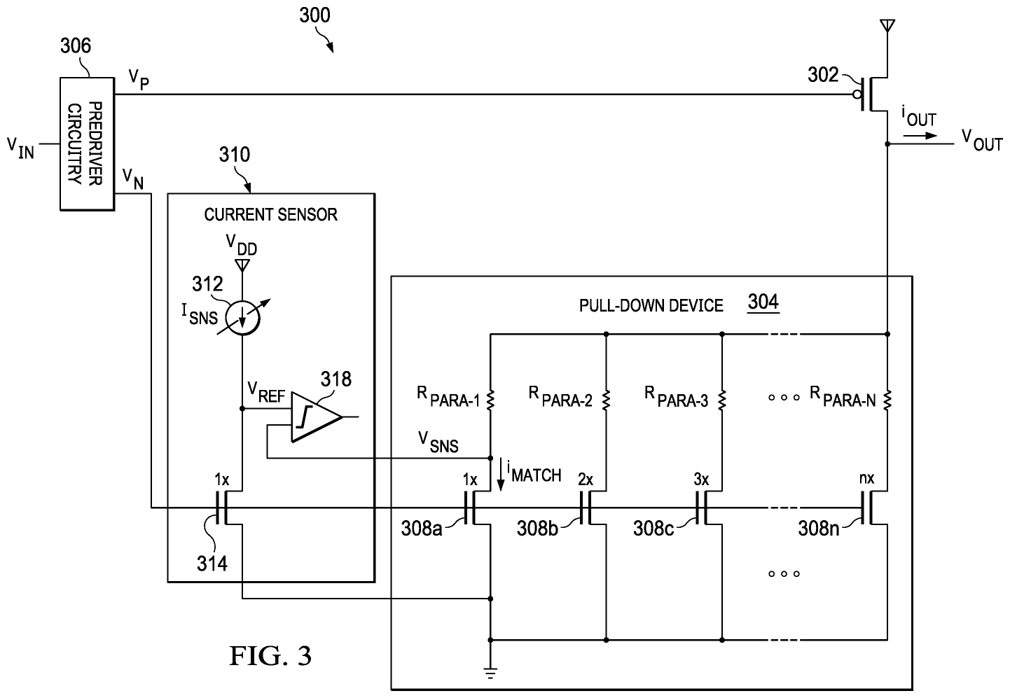

FIG. 3 illustrates selected components of an example switched output stage 300 for a power converter, in accordance with embodiments of the present disclosure. As shown in FIG. 3, switched output stage 300 may include a pull-up device 302 (e.g., a switch, a p-type metal-oxide-semiconductor field effect transistor, etc.) coupled at its non-gate terminals between a supply voltage and an output node and a pull-down device 304 coupled at its non-gate terminals between a ground voltage and the output node. As also shown in FIG. 3, pull-down device 304 may be implemented with a plurality of pull-down elements 308 (e.g., pull-down elements 308a, 308b, 308c, . . . , 308n) arranged electrically in parallel to one another, each with an associated parasitic resistance (e.g., R_{PARA-1}, R_{PARA-2}, R_{PARA-3}, . . . , R_{PARA-N}). Each of pull-down elements 308 may be implemented with a switch, an n-type metal-oxide-semiconductor field effect transistor, or other suitable electronic device.

Predriver circuitry 306 may receive an input voltage v_{IN} (typically a pulse-width-modulated input voltage signal) and apply control logic and/or buffering to such input voltage to drive a pull-up device driving signal voltage v_{P} to the gate terminal of pull-up device 302 and to drive a pull-down device driving signal voltage v_{N} to the gate terminal of pull-down device 304, wherein v_{P} and v_{N} are each a function of v_{N} Accordingly, switched output stage 300 may generate an output voltage v_{OUT} to its output node which is a function of v_{IN}.

As further shown in FIG. 3, switched output stage 300 may include a current sensor 310 configured to sense output current i_{OUT} generated by switched output stage 300. As shown in FIG. 3, current sensor 310 may include a variable current source 312 (e.g., a current digital-to-analog converter) configured to generate a variable current ism. Variable current ism may be driven through a sense pull-down device 314 which may be gate-coupled and source-coupled to a matching pull-down element 308 (e.g., pull-down element 308a) of pull-down device 304. “Matching” as used herein means that sense pull-down device 314 may be sized substantially identical to (i.e., as identical as possible given process constraints and design tolerances) matching pull-down element 308a with conductive routing for sense pull-down device 314 and matching pull-down element 308a being as similar as possible. Accordingly, pull-down device 304 may be sized substantially larger than sense pull-down device 314, but a matching pull-down element 308 may be similar in many respects to sense pull-down device 314 in terms of size and electrical characteristics. Further, pull-down device 314 may be located proximate to matching pull-down element 308a in the physical design and layout of switched output stage 300 (e.g., sense pull-down device 314 may be located closer to matching pull-down element 308a than to any other pull-down element 308).

Also as depicted in FIG. 3, current sensor 310 may include a comparator 318 configured to compare a reference voltage v_{REF} across pull-down device 314 (and taken from a sense point as close to the drain terminal of pull-down device 314 as possible) to a sense voltage v_{SNS} across matching pull-down element 308a (and taken from a sense point as close to the drain terminal of matching pull-down element 308a as possible). Such comparison may determine a point at which a current WATCH through matching pull-down element 308a equals variable current i_{SNS}, which may be indicated when reference voltage v_{REF} equals sense voltage v_{SNS} Having identified current i_{MATCH}, output current i_{OUT} may be determined as the product of a fixed current ratio α and current i_{MATCH} (e.g., i_{OUT}=αi_{MATCH}).

Advantageously, switched output stage 300 may not require metal resistance matching between the sense path within current sensor 310 and the pull-down path of switched output stage 300, provided that current through the pull-down path of switched output stage 300 is evenly distributed among pull-down elements 308 in accordance with their respective sizes. Because of matching between pull-down device 314 and matching pull-down element 308a, the current ratio between pull-down device 314 and matching pull-down element 308a may not be significantly affected by changes in temperature. Further, the current ratio between matching pull-down element 308a and the remainder of pull-down elements 308 may also have little or no variation with temperature. Accordingly, current sensor 310 may accurately detect current flowing through pull-down device 304, with little or no sensitivity to changes in temperature.

Although the foregoing paragraph contemplates current sensing of the pull-down path of switched output stage 300, an equivalent dual of current sensor 310 and pull-down device 304 (e.g., a pull-up device 302 with pull-down elements equivalent to pull-down elements 308) may be used, in addition to or in lieu of current sensor 310, for current sensing of the pull-up path of switched output stage 300.

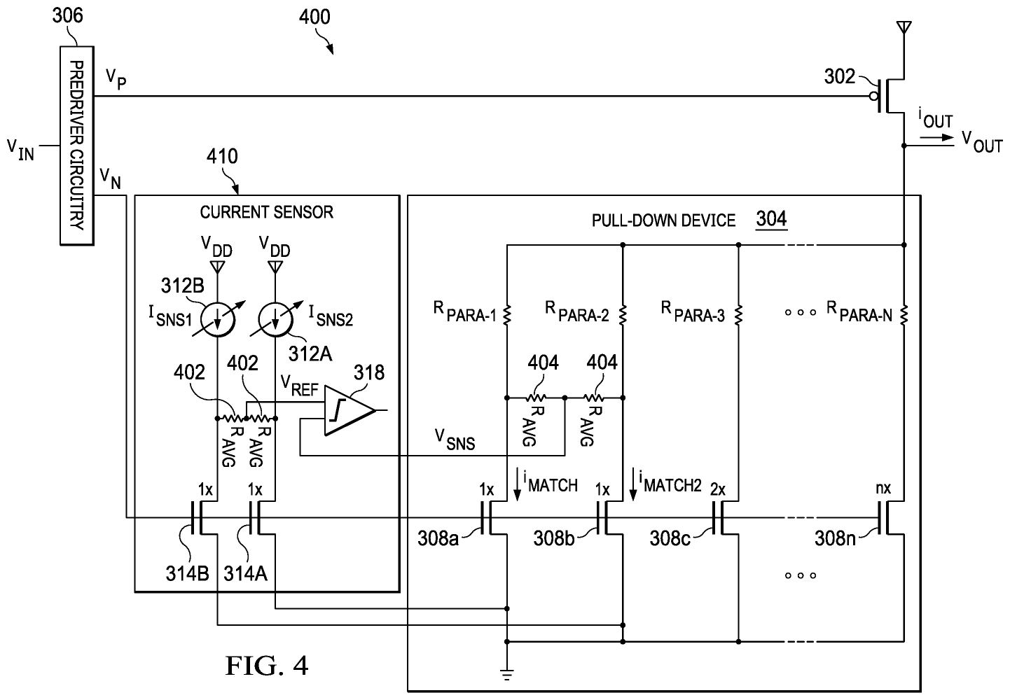

FIG. 4 illustrates selected components of an example switched output stage 400 for a power converter, in accordance with embodiments of the present disclosure. Switched output stage 400 shown in FIG. 4 is similar in many respects to switched output stage 300 of FIG. 3. Accordingly, only the main differences between switched output stage 300 and switched output stage 400 may be discussed below.

As shown in FIG. 4, switched output stage 400 may include a current sensor 410 configured to sense output current i_{OUT} generated by switched output stage 400. As further shown in FIG. 4, current sensor 410 may include a variable current source 312A (e.g., a current digital-to-analog converter) configured to generate a variable current i_{SNS1}. Variable current i_{SNS}1 may be driven through a sense pull-down device 314A which may be gate-coupled and source-coupled to a matching pull-down element 308 (e.g., pull-down element 308a) of pull-down device 304. Similarly, current sensor 410 may also include a variable current source 312B (e.g., a current digital-to-analog converter) configured to generate a variable current i_{SNS2} Variable current i_{SNS2} may be driven through a sense pull-down device 314B which may be gate-coupled and source-coupled to a matching pull-down element 308 (e.g., pull-down element 308b) of pull-down device 304. Current sensor 410 may also include two averaging resistors 402 coupled in series between the respective drain terminals of each of sense pull-down device 314A and sense pull-down device 314B, such that an average of the respective drain voltages is generated between the two averaging resistors 402 as a reference voltage v_{REF} representative as the average of currents I_{SNS1} and I_{SNS2}. The resistances Rave of averaging resistors 402 may be selected such that negligible or minimal current flows through averaging resistors 402.

In addition, pull-down device 304 may include two averaging resistors 404 coupled in series between the respective drain terminals of each of matching pull-down element 308a and matching pull-down element 308b, such that an average of the respective drain voltages is generated between the two averaging resistors 404 as a sense voltage v_{SNS} representative as the average of current i_{MATCH1} flowing through matching pull-down element 308a and current i_{MATCH2} flowing through matching pull-down element 308b. The resistances Rave of averaging resistors 404 may be selected such that negligible or minimal current flows through averaging resistors 404.

Comparator 318 of current sensor 410 may be configured to compare reference voltage V_{REF} across to a sense voltage V_{SNS}. Such comparison may determine a point at which the average of currents i_{MATCH1} and i_{MATCH2} through matching pull-down element 308a equals the average of variable currents i_{SNS}1 and i_{SNS2}, which may be indicated when reference voltage V_{REF} equals sense voltage V_{SNS}. Having identified an average for currents i_{MATCH1} and i_{MATCH2}, output current i_{OUT} may be determined as the product of a fixed current ratio α and current i_{MATCH} (e.g., i_{OUT}=α·average(i_{MATCH1}, i_{MATCH2})).

Although the foregoing paragraph contemplates current sensing of the pull-down path of switched output stage 400, an equivalent dual of current sensor 410 and pull-down device 304 (e.g., a pull-up device 302 with pull-down elements equivalent to pull-down elements 308) may be used, in addition to or in lieu of current sensor 410, for current sensing of the pull-up path of switched output stage 400.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A system comprising:
an output power stage driver comprising a plurality of parallel-coupled field-effect transistors; and
a current sensor comprising a sense field-effect transistor matched to a matched field-effect transistor of the plurality of parallel-coupled field-effect transistors and gate-coupled and source-coupled to the matched field-effect transistor, wherein the current sensor is configured to:
measure a reference voltage across the sense field-effect transistor;
measure a sense voltage across the matched field-effect transistor; and
determine a current through the output power stage driver based on a comparison of the reference voltage to the sense voltage.

2. The system of claim 1, wherein the plurality of parallel-coupled field-effect transistors and the sense field-effect transistor are n-type metal-oxide-semiconductor field-effect transistors.

3. The system of claim 1, wherein the plurality of parallel-coupled field-effect transistors and the sense field-effect transistor are p-type metal-oxide-semiconductor field-effect transistors.

4. The system of claim 1, wherein the current sensor further comprises a second sense field-effect transistor matched to a second matched field-effect transistor of the plurality of parallel-coupled field-effect transistors and gate-coupled and source-coupled to the second matched field-effect transistor, wherein the current sensor is further configured to:
measure an average reference voltage across the sense field-effect transistor and the second field-effect transistor;
measure an average sense voltage across the matched field-effect transistor and the second matched field-effect transistor; and
determine the current through the output power stage driver based on a comparison of the average reference voltage to the average sense voltage.

5. A method comprising, in a system including an output power stage driver comprising a plurality of parallel-coupled field-effect transistors:
measuring a reference voltage across a sense field-effect transistor matched to a matched field-effect transistor of the plurality of parallel-coupled field-effect transistors and gate-coupled and source-coupled to the matched field-effect transistor;
measuring a sense voltage across the matched field-effect transistor; and
determining a current through the output power stage driver based on a comparison of the reference voltage to the sense voltage.

6. The method of claim 5, wherein the plurality of parallel-coupled field-effect transistors and the sense field-effect transistor are n-type metal-oxide-semiconductor field-effect transistors.

7. The method of claim 5, wherein the plurality of parallel-coupled field-effect transistors and the sense field-effect transistor are p-type metal-oxide-semiconductor field-effect transistors.

8. The method of claim 5, further comprising:
measuring an average reference voltage across the sense field-effect transistor and a second field-effect transistor matched to a second matched field-effect transistor of the plurality of parallel-coupled field-effect transistors and gate-coupled and source-coupled to the second matched field-effect transistor;
measuring an average sense voltage across the matched field-effect transistor and the second matched field-effect transistor; and
determining the current through the output power stage driver based on a comparison of the average reference voltage to the average sense voltage.
